(19) United States
(12) Patent Application Publication
(10) Pub. No.: US 2026/0089889 A1
(43) Pub. Date: Mar. 26, 2026

(54) HEAT SINK UNIT, HEAT SINK ASSEMBLY AND ELECTRONIC DEVICE

(71) Applicant: Wistron NeWeb Corporation, Hsinchu (TW)

(72) Inventors: Ying-Chih LIU, Hsinchu (TW); Yi-Chieh LIN, Hsinchu (TW); Chien-Hung LEE, Hsinchu (TW); Yu-Fu KU, Hsinchu (TW); Bo-Yen CHEN, Hsinchu (TW)

(21) Appl. No.: 19/056,874

(22) Filed: Feb. 19, 2025

(30) Foreign Application Priority Data
Sep. 24, 2024 (TW) 113136196

(51) Int. Cl. H05K 7/20; H05K 1/02

(52) U.S. Cl. CPC H05K 7/20409; H05K 1/0203; H05K 7/20436; H05K 7/20509; H05K 2201/066

(57) ABSTRACT

A heat sink unit includes a first plate portion and a second plate portion. The first plate portion is integrally formed and includes an outer surface, an inner surface and at least one protrusion. The second plate portion is connected to the first plate portion. A first angle between the first plate portion and the second plate portion is between 5 degrees and 175 degrees. The outer surface of the first plate portion is farther from the second plate portion than the inner surface therefrom, and the protrusion is located on the outer surface.

### RELATED APPLICATIONS

This application claims the benefit of priority to Taiwan Patent Application No. 113136196, filed on Sep. 24, 2024. The entire content of the above identified application is incorporated herein by reference.

### BACKGROUND

### Technical Field

The present disclosure relates to a heat sink unit, a heat sink assembly and an electronic device, and more particularly to a heat sink unit and heat sink assembly including a protrusion, and an electronic device applying the heat sink unit and/or the heat sink assembly.

### Description of Related Art

With the advancement of electronic device functions, such as network communication devices under high-speed transmission requirements, in addition to solving higher power consumption and the resulting heat dissipation issues, consideration must also be given to home placement requirements for balancing size, weight, and shape.

For example, conventional heat sinks often use aluminum extrusion processes; such heat sinks have disadvantages on heavier weight, limited shape design, only being capable of forming relatively simple geometric shapes, and requiring more post-processing and assembly structures, at the same time also resulting in higher carbon emissions. Therefore, in current heat sink markets, there is an urgent need to develop a heat sink that can solve the aforementioned problems.

### SUMMARY

A heat sink unit is provided according to an aspect of the present disclosure, the heat sink unit includes a first plate portion and a second plate portion. The first plate portion is integrally formed and includes an outer surface, an inner surface, and at least one protrusion. The second plate portion is connected to the first plate portion. A first angle between the first plate portion and the second plate portion is between 5 degrees and 175 degrees, the outer surface of the first plate portion is farther from the second plate portion than the inner surface therefrom, and the at least one protrusion is located on the outer surface.

A heat sink assembly is provided according to another aspect of the present disclosure, the heat sink assembly includes a first heat sink unit and a second heat sink unit. The first heat sink unit includes a first plate portion and a second plate portion. The first plate portion includes at least one protrusion. The second plate portion is connected to the first plate portion, the first plate portion and the second plate portion are integrally formed, and a first angle between the first plate portion and the second plate portion is between 5 degrees and 175 degrees. The second heat sink unit includes a fifth plate portion and a sixth plate portion. The sixth plate portion is connected to the fifth plate portion, and a second angle between the fifth plate portion and the sixth plate portion is between 5 degrees and 175 degrees. The first heat sink unit is connected to the second heat sink unit.

An electronic device is provided according to yet another aspect of the present disclosure, the electronic device includes a heat sink unit and at least one circuit board assembly. The heat sink unit includes a first plate portion and a second plate portion. The first plate portion includes at least one protrusion. The second plate portion is connected to the first plate portion, the first plate portion and the second plate portion are integrally formed, and a first angle between the first plate portion and the second plate portion is between 5 degrees and 175 degrees. The at least one circuit board assembly includes at least one circuit board and at least one electronic component, and the electronic component is disposed on the circuit board and connected to the protrusion.

### BRIEF DESCRIPTION OF THE DRAWINGS

The present disclosure can be more fully understood by reading the following detailed description of the embodiment, with reference made to the accompanying drawings as follows:

FIG. 1A illustrates a three-dimensional view of a heat sink assembly according to a first embodiment of the present disclosure.

FIG. 1B illustrates a three-dimensional view of a first heat sink unit of the heat sink assembly of FIG. 1A.

FIG. 1C illustrates a three-dimensional view of an original plate of the first heat sink unit in FIG. 1B before bending.

FIG. 1D illustrates a three-dimensional view of a second heat sink unit of the heat sink assembly in FIG. 1A.

FIG. 1E illustrates a three-dimensional view of an original plate of the second heat sink unit in FIG. 1D before bending.

FIG. 2A illustrates a three-dimensional view of a heat sink unit according to a second embodiment of the present disclosure.

FIG. 2B illustrates a three-dimensional view of an original plate of the heat sink unit in FIG. 2A before bending.

FIG. 3A illustrates a three-dimensional view of a heat sink unit according to a third embodiment of the present disclosure.

FIG. 3B illustrates a three-dimensional view of an original plate of the heat sink unit in FIG. 3A before bending.

FIG. 4A illustrates an exploded view of an electronic device according to a fourth embodiment of the present disclosure.

FIG. 4B illustrates a three-dimensional view of the electronic device in FIG. 4A.

FIG. 4C illustrates a cross-sectional view of partial elements of the electronic device along line 4C-4C in FIG. 4B.

### DETAILED DESCRIPTION

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

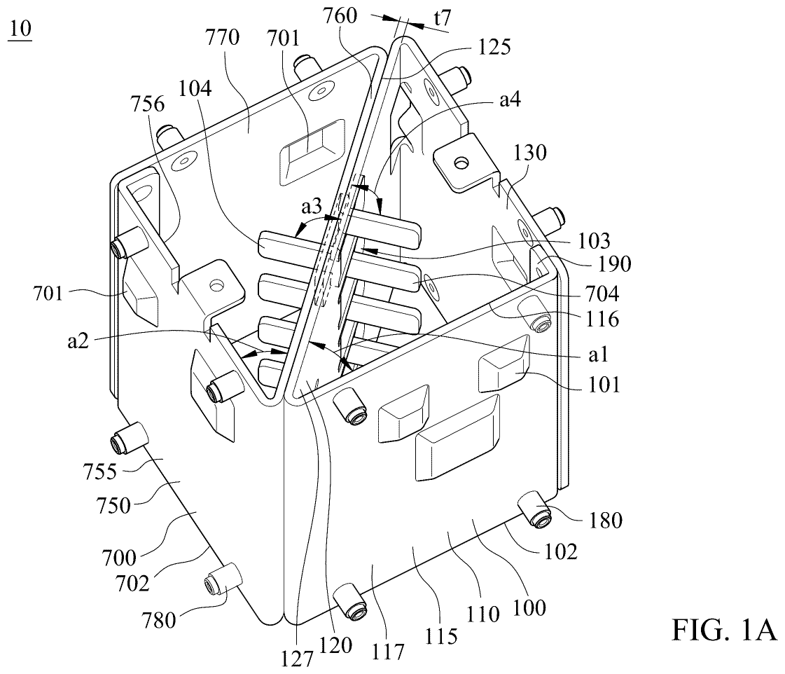

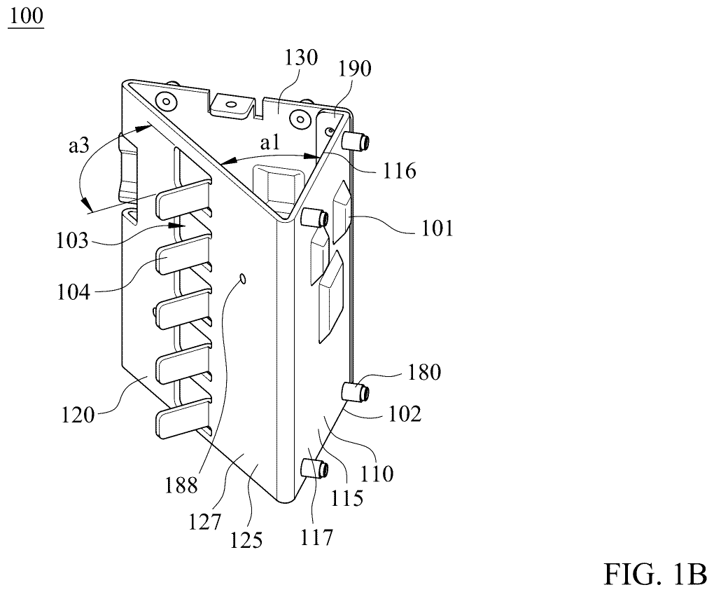

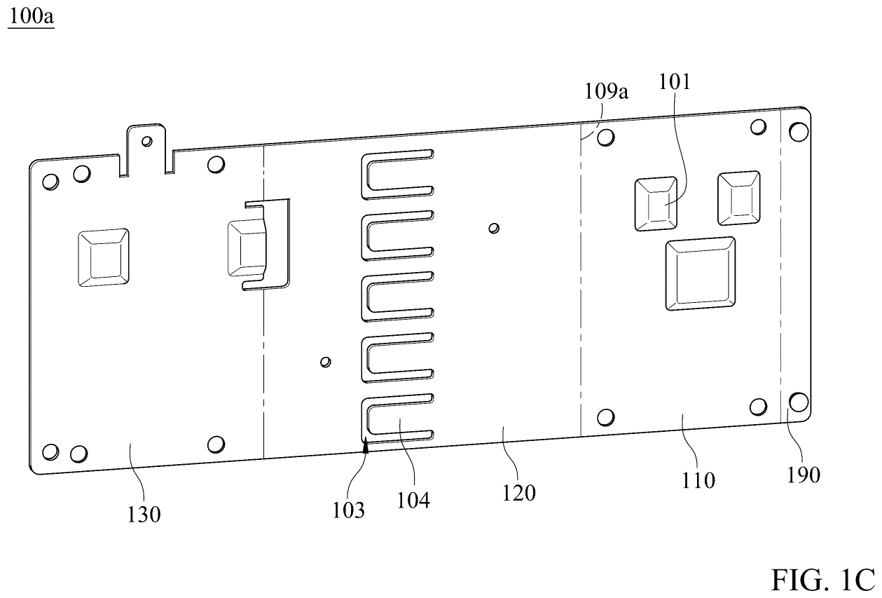

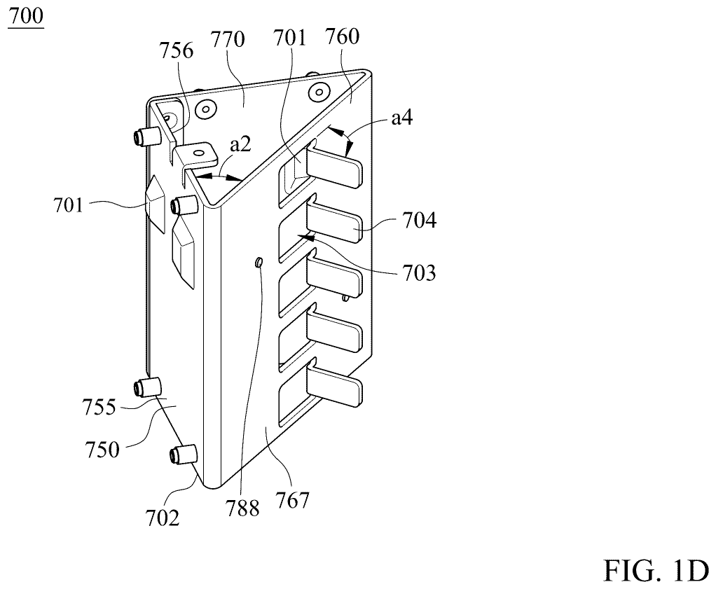

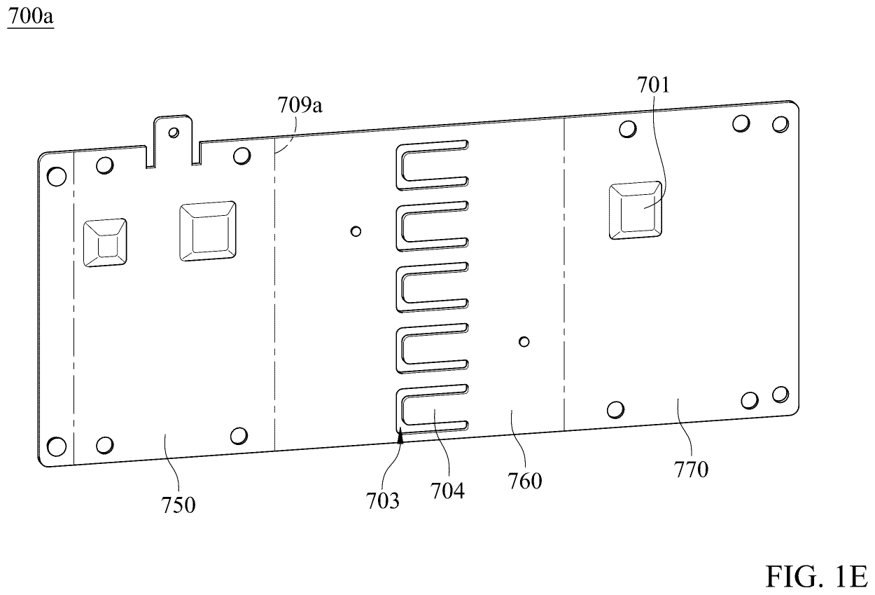

FIG. 1A illustrates a three-dimensional view of a heat sink assembly 10 according to a first embodiment of the present disclosure. Referring to FIG. 1A, the heat sink assembly 10 includes two heat sink units (i.e., a first heat sink unit 100 and a second heat sink unit 700). The first heat sink unit 100 includes a first plate portion 110 and a second plate portion 120. The first plate portion 110 includes at least one protrusion 101. The second plate portion 120 is connected to the first plate portion 110, and a first angle a1 between the first plate portion 110 and the second plate portion 120 is between 5 degrees and 175 degrees. The second heat sink unit 700 includes a fifth plate portion 750 and a sixth plate portion 760. The sixth plate portion 760 is connected to the fifth plate portion 750, and a second angle a2 between the fifth plate portion 750 and the sixth plate portion 760 is between 5 degrees and 175 degrees. The first heat sink unit 100 is connected to the second heat sink unit 700. Accordingly, the heat source of the object to be cooled contacts the protrusion 101, thereby dissipating heat through thermal conduction, and designing the protrusion 101 only at high heat dissipation demanding positions is advantageous in reducing the cost and weight of the heat sink assembly 10, and improving processing flexibility, while maintaining heat dissipation efficiency. Furthermore, each of the first angle a1 and the second angle a2 can be between 30 degrees and 120 degrees. In the first embodiment, each of the first angle a1 and the second angle a2 is about 45 degrees, and the present disclosure is not limited thereto.

FIG. 1B illustrates a three-dimensional view of the first heat sink unit 100 in the heat sink assembly 10 of FIG. 1A. Referring to FIG. 1B, the first plate portion 110 is integrally formed and includes an outer surface 115, an inner surface 116, and the protrusion 101. The outer surface 115 of the first plate portion 110 is farther from the second plate portion 120 than the inner surface 116 therefrom, and the protrusion 101 is located on the outer surface 115. Accordingly, the heat sink unit according to the present disclosure is advantageous in reducing cost and weight, and improving processing flexibility, while maintaining heat dissipation efficiency. Furthermore, the first plate portion 110 and the second plate portion 120 can be integrally formed.

Specifically, the protrusion 101 might not be connected to the opposite edges 102 of the first plate portion 110. Accordingly, this helps to reduce cost and weight, and improve processing flexibility.

The first plate portion 110 and the second plate portion 120 can be integrally formed from a metal material, and the thickness t7 of each of the main body area 117 of the first plate portion 110 and the main body area 127 of the second plate portion 120 can be between 0.8 mm and 3 mm. Accordingly, the first plate portion 110 and the second plate portion 120 can further be formed using a cost-effective sheet metal forming process, while maintaining heat dissipation capabilities to meet product heat dissipation performance requirements.

FIG. 1C illustrates a three-dimensional view of an original plate 100a of the first heat sink unit 100 in FIG. 1B before bending, and not all bending lines 109a on the original plate 100a are shown in FIG. 1C. Referring to FIG. 1C, the first plate portion 110 and the second plate portion 120 can be formed by bending along the bending lines 109a on the original plate 100a, and the protrusion 101 can be formed by sheet metal forming of the first plate portion 110. Accordingly, the design of conventional heat sinks using aluminum extrusion or die casting processes increases part weight, and relies on more post-processing and assembly processes to compensate for thermal interface requirements, thus inevitably increasing cost and weight despite maintaining heat dissipation performance; in contrast, the heat sink unit and assembly according to the present disclosure can simultaneously achieve efficacies of weight reduction, cost savings, and reduced design and process complexity. Furthermore, an integrated protrusion structure can be formed through sheet metal bending or drawing processes, allowing the heat source to directly engage with or attach to the protrusion 101 of the first heat sink unit 100 without going through other mediums in-between. Specifically, the original plate 100a is a high thermal conductivity aluminum sheet with the thickness t7 between 1 mm and 2 mm, and the present disclosure is not limited thereto.

Referring to FIG. 1B, the first heat sink unit 100 may further include a third plate portion 130; the first plate portion 110, the second plate portion 120, and the third plate portion 130 can be formed by bending along the bending lines 109a on the original plate 100a and can be sequentially connected and form a closed shape. Accordingly, the heat dissipation requirements of hollow circuit board assemblies in electronic devices can be met. Furthermore, the first heat sink unit 100 may further include a joint 190, and the joint 190 is fixed to the third plate portion 130 through riveting or welding. In other embodiments of the present disclosure (not shown in drawings), the heat sink unit might not form a closed shape.

The closed shape can be a polygon. Furthermore, the closed shape can be a triangle or a quadrilateral; the first plate portion 110, the second plate portion 120, and the third plate portion 130 are specifically sequentially connected and form a triangle. Accordingly, the first heat sink unit 100 forming the triangle through riveting or welding can effectively reduce part weight.

At least one plate portion of the first plate portion 110 and the second plate portion 120 (specifically the second plate portion 120) may include a main body area 127, one or multiple first openings 103, and one or multiple first raised pieces 104. Each first raised piece 104 is formed by processing a corresponding first opening 103, and each first raised piece 104 is connected to the main body area 127. A first raised angle a3 between the main body area 127 and each first raised piece 104 can be between 5 degrees and 175 degrees. Accordingly, the surface area of the first heat sink unit 100 is increased, and heat is distributed by conduction to relatively empty spaces. Specifically, the boundary of each first raised piece 104 is cut out from the main body area 127 of the original plate 100a, with one end of the first raised piece 104 being connected to the main body area 127 for bending, and the other end thereof being an open end. In embodiments of the present disclosure, the first raised piece can bend outward or inward relative to the closed shape, or can also not bend.

FIG. 1D illustrates a three-dimensional view of the second heat sink unit 700 of the heat sink assembly 10 in FIG. 1A. Referring to FIG. 1D, the second heat sink unit 700 includes a fifth plate portion 750 and a sixth plate portion 760. The fifth plate portion 750 is integrally formed and includes an outer surface 755, an inner surface 756, and at least one protrusion 701. The sixth plate portion 760 is connected to the fifth plate portion 750. A second angle a2 between the fifth plate portion 750 and the sixth plate portion 760 is between 5 degrees and 175 degrees. The outer surface 755 of the fifth plate portion 750 is farther from the sixth plate portion 760 than the inner surface 756 therefrom, and the protrusion 701 is located on the outer surface 755.

Specifically, the protrusion 701 is not connected to the opposite two edges 702 of the fifth plate portion 750. The second heat sink unit 700 further includes a seventh plate portion 770; the fifth plate portion 750, the sixth plate portion 760, and the seventh plate portion 770 are sequentially connected and form a closed shape, and the closed shape is a triangle. Furthermore, one or multiple plate portions of the sixth plate portion 760 and the seventh plate portion 770 may include the protrusion 701, and the protrusion 701 is not connected to the opposite two edges 702 of the plate portion that it is disposed on.

FIG. 1E illustrates a three-dimensional view of an original plate 700a of the second heat sink unit 700 in FIG. 1D before bending, and not all bending lines 709a on the original plate 700a are shown in FIG. 1E. Referring to FIGS. 1D and 1E, the fifth plate portion 750, the sixth plate portion 760, and the seventh plate portion 770 are integrally formed from a metal material, and the thickness of a main body area of each of the fifth plate portion 750, the sixth plate portion 760, and the seventh plate portion 770 is between 0.8 mm and 3 mm.

Furthermore, the fifth plate portion 750 and the sixth plate portion 760 are formed by bending the original plate 700a of a metal material. Specifically, the fifth plate portion 750, the sixth plate portion 760, and the seventh plate portion 770 are formed by bending along the bending lines 709a on the original plate 700a, and the protrusion 701 is formed by sheet metal forming of the plate portion that it is disposed on (e.g., the fifth plate portion 750).

One plate portion of the fifth plate portion 750 and the sixth plate portion 760 (specifically the sixth plate portion 760) includes a main body area 767, one or multiple second openings 703, and one or multiple second raised pieces 704. Each second raised piece 704 is formed by processing a corresponding second opening 703, and each second raised piece 704 is connected to the main body area 767. A second raised angle a4 between the main body area 767 and each second raised piece 704 is between 5 degrees and 175 degrees. Furthermore, each of the first raised angle a3 and the second raised angle a4 can be between 45 degrees and 135 degrees. Specifically, each of the first raised angle a3 and the second raised angle a4 is about 90 degrees, and the present disclosure is not limited thereto.

Referring to FIGS. 1A to 1E, a portion of an outer surface 125 of the second plate portion 120 is connected to the sixth plate portion 760, and the ratio of the area of said portion to the area of the outer surface 125 of the second plate portion 120 can be between 0.5 and 1. Accordingly, the triangular first heat sink unit 100 and the triangular second heat sink unit 700 are further assembled together to form a rectangular/square structure, which can replace conventional square-shaped aluminum extruded heat sink fins, and can effectively reduce the weight to 35% or less of the conventional technology. Furthermore, the ratio of the area of said portion to the area of the outer surface 125 of the second plate portion 120 can be between 0.75 and 1. Specifically, the second plate portion 120 and the sixth plate portion 760 respectively include multiple positioning structures 188, 788, to position and connect the second plate portion 120 and the sixth plate portion 760. In other embodiments of the present disclosure, other heat sink units can also be assembled according to actual heat dissipation requirements, so as to implement more complex thermal conduction structures, achieving overall heat dissipation and balancing cost and weight.

The main body area 127 of the second plate portion 120 can be connected to the main body area 767 of the sixth plate portion 760; the first raised pieces 104 respectively pass through the second openings 703, and the second raised pieces 704 respectively pass through the first openings 103. Accordingly, the intermediate portion of the heat sink assembly 10 employs multiple bends to increase surface area, and distributes heat by conduction to relatively empty spaces. Furthermore, the first heat sink unit 100 and the second heat sink unit 700 can further respectively include multiple stand-offs 180, 780, so as to be fixed to the object to be cooled (e.g., a circuit board assembly of the electronic device 40 in the fourth embodiment).

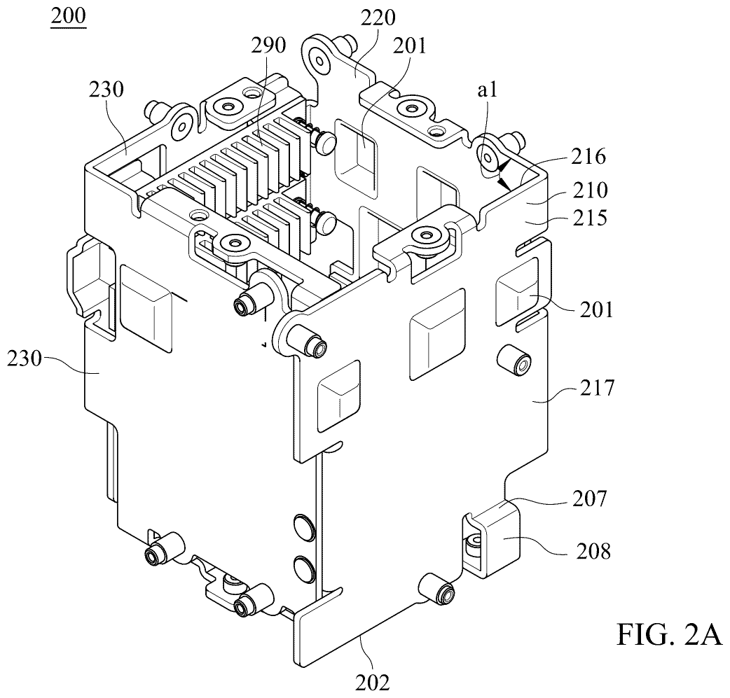

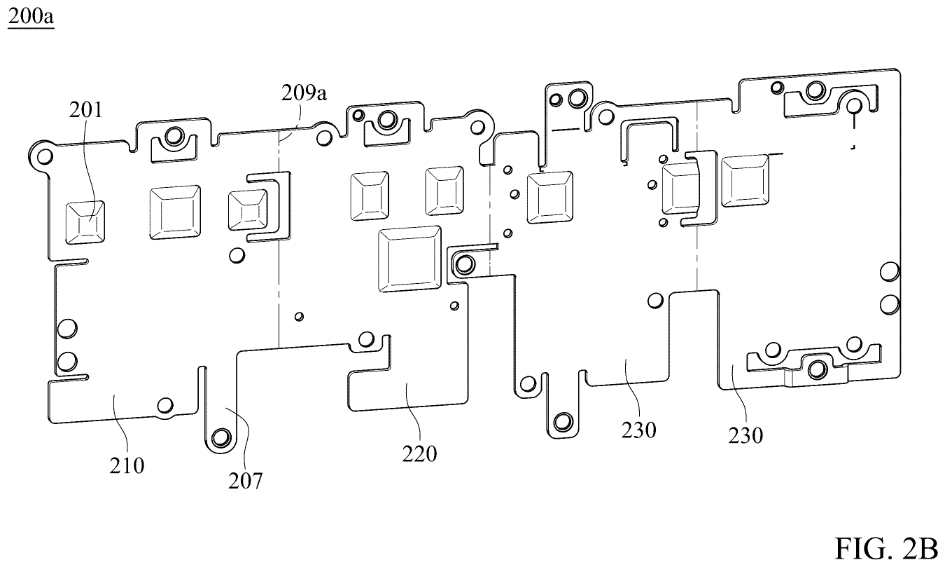

FIG. 2A illustrates a three-dimensional view of a heat sink unit 200 according to a second embodiment of the present disclosure. Referring to FIG. 2A, the heat sink unit 200 includes a first plate portion 210 and a second plate portion 220. The first plate portion 210 is integrally formed and includes an outer surface 215, an inner surface 216, and at least one protrusion 201. The second plate portion 220 is connected to the first plate portion 210. A first angle a1 between the first plate portion 210 and the second plate portion 220 is between 5 degrees and 175 degrees. The outer surface 215 of the first plate portion 210 is farther from the second plate portion 220 than the inner surface 216 therefrom, and the protrusion 201 is located on the outer surface 215. In the second embodiment, the first angle a1 is about 90 degrees.

Specifically, the protrusion 201 is not connected to the opposite two edges 202 of the first plate portion 210. The heat sink unit 200 further includes two third plate portions 230; the first plate portion 210, the second plate portion 220, and the two third plate portions 230 are sequentially connected and form a closed shape, and the closed shape is quadrilateral. Furthermore, one or multiple plate portions of the second plate portion 220 and the two third plate portions 230 may include the protrusion 201, and the protrusion 201 is not connected to the opposite two edges 202 of the plate portion that it is disposed on.

FIG. 2B illustrates a three-dimensional view of an original plate 200a of the heat sink unit 200 in FIG. 2A before bending, and not all bending lines 209a on the original plate 200a are shown in FIG. 2B. Referring to FIGS. 2A and 2B, the first plate portion 210, the second plate portion 220, and the two third plate portions 230 are integrally formed from a metal material, and the thickness of a main body area of each of the first plate portion 210, the second plate portion 220, and the two third plate portions 230 is between 0.8 mm and 3 mm. Furthermore, the first plate portion 210, the second plate portion 220, and the two third plate portions 230 are formed by bending along the bending lines 209a on the original plate 200a, and the protrusion 201 is formed by sheet metal forming of the plate portion that it is disposed on (e.g., the first plate portion 210).

Referring to FIG. 2A, at least one plate portion of the first plate portion 210, the second plate portion 220, and the two third plate portions 230 (e.g., the first plate portion 210) includes a main body area 217 and a step structure 207. One end of the step structure 207 is connected to the main body area 217, and the other end of the step structure 207 is an open end. The step structure 207 has a step shape and includes a plurality of step surfaces (e.g., a step surface 208). Therefore, various heat dissipation structures can be designed using the bending flexibility of the original plate 200a, which can meet various heat source distribution requirements.

The step surface 208 protrudes from the outer surface 215 of the first plate portion 210 and is parallel to the main body area 217. Therefore, the step surface 208 can directly contact the heat source.

The heat sink unit 200 may further include at least one fin element 290, which is connected to at least one plate portion of the first plate portion 210, the second plate portion 220, and the two third plate portions 230 (e.g., one of the two third plate portions 230). The heat dissipation requirements of high heat sources are accordingly met. Furthermore, the one of the two third plate portions 230 and the fin element 290 might not be integrally formed, and the fin element 290 can be connectively fixated to the one of the two third plate portions 230 through a flexible fastener.

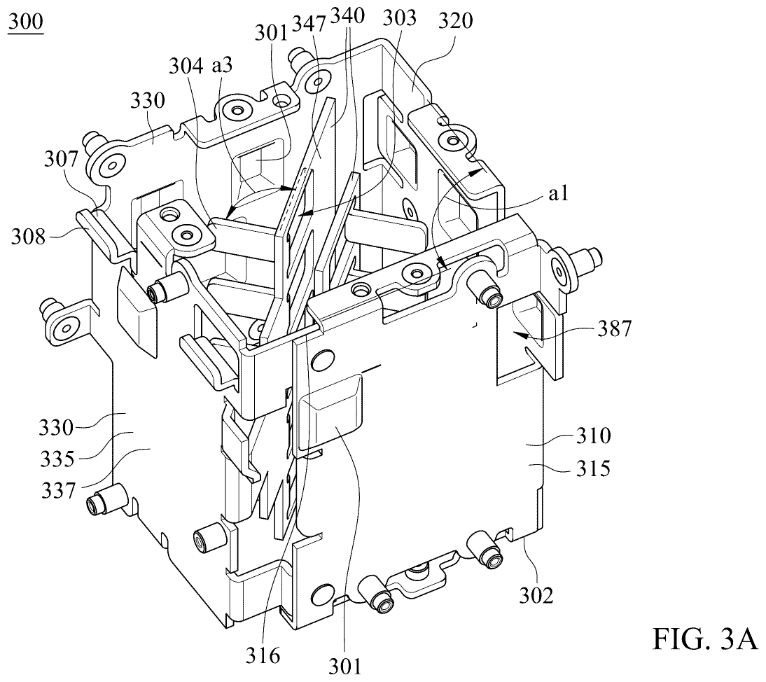

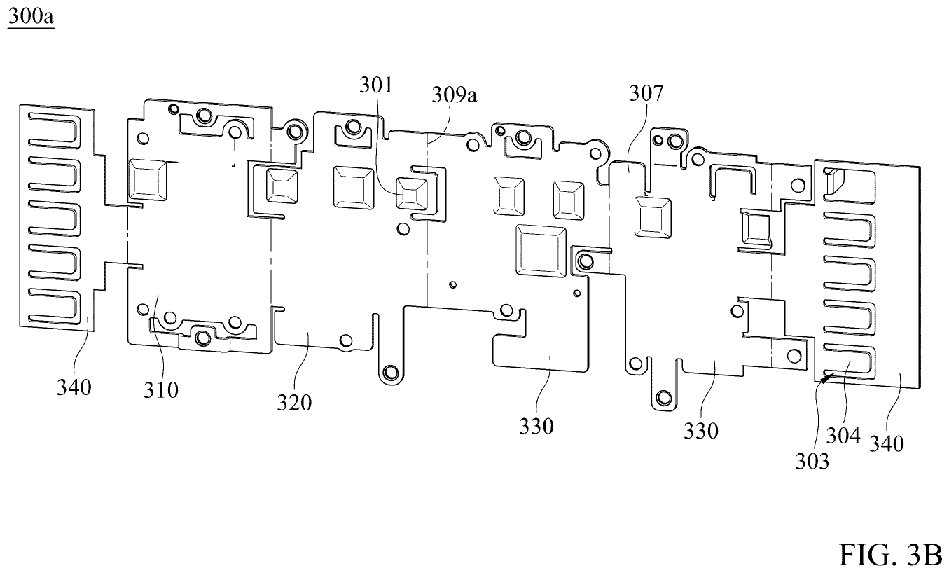

FIG. 3A illustrates a three-dimensional view of a heat sink unit 300 according to a third embodiment of the present disclosure. Referring to FIG. 3A, the heat sink unit 300 includes a first plate portion 310 and a second plate portion 320. The first plate portion 310 is integrally formed and includes an outer surface 315, an inner surface 316, and at least one protrusion 301. The second plate portion 320 is connected to the first plate portion 310. A first angle a1 between the first plate portion 310 and the second plate portion 320 is between 5 degrees and 175 degrees. The outer surface 315 of the first plate portion 310 is farther from the second plate portion 320 than the inner surface 316 therefrom, and the protrusion 301 is located on the outer surface 315. In the third embodiment, the first angle a1 is about 90 degrees.

Specifically, the protrusion 301 is not connected to the opposite two edges 302 of the first plate portion 310. The heat sink unit 300 further includes two third plate portions 330; the first plate portion 310, the second plate portion 320, and the two third plate portions 330 are sequentially connected and form a closed shape, the closed shape is quadrilateral. Furthermore, one or multiple plate portions of the second plate portion 320 and the two third plate portions 330 may include the protrusion 301, and the protrusion 301 is not connected to the opposite two edges 302 of the plate portion that it is disposed on.

FIG. 3B illustrates a three-dimensional view of an original plate 300a of the heat sink unit 300 in FIG. 3A before bending, and not all bending lines 309a on the original plate 300a are shown in FIG. 3B. Referring to FIGS. 3A and 3B, the first plate portion 310, the second plate portion 320, and the two third plate portions 330 are integrally formed from a metal material, and the thickness of a main body area of each of the first plate portion 310, the second plate portion 320, and the two third plate portions 330 can be between 0.8 mm and 3 mm. Furthermore, the first plate portion 310, the second plate portion 320, and the two third plate portions 330 are formed by bending along the bending lines 309a on an original plate 300a, and the protrusion 301 is formed by sheet metal forming of the plate portion that it is disposed on (e.g., the first plate portion 310).

Referring to FIG. 3A, at least one plate portion of the first plate portion 310, the second plate portion 320, and the two third plate portions 330 (e.g., one of the two third plate portions 330) includes a main body area 337 and a step structure 307. One end of the step structure 307 is connected to the main body area 337, and the other end of the step structure 307 is an open end. The step structure 307 has a step shape and includes multiple step surfaces (e.g., a step surface 308). The step surface 308 protrudes from an outer surface 335 of the one of the third plate portions 330 and is parallel to the main body area 337. In addition, the heat sink unit 300 further includes an avoidance structure 387 for avoiding electronic components that relatively protrude more from the circuit board. Both the step structure 307 and the avoidance structure 387 are formed by bending or hollowing out the original plate 300a, so no additional processing and assembly steps are required. In the embodiments of the present disclosure, the step structure and avoidance structure can be designed on any plate portion according to heat dissipation requirements.

The heat sink unit 300 further includes two fourth plate portions 340, located on an inner side of the closed shape and respectively connected to the first plate portion 310 and one of the two third plate portions 330. Accordingly, the heat dissipation surface area of the interior of the closed shape is increased.

The other one of the two fourth plate portions 340, the first plate portion 310, the second plate portion 320, the two third plate portions 330 and the one of the two fourth plate portions 340 are formed by bending along the original plate 300a along a surrounding direction. Accordingly, utilizing the advantage of the original plate 300a that does not require additional processing, the heat dissipation area of the interior of the closed shape is increased.

Each of the two fourth plate portions 340 may include a main body area 347, at least one first opening 303, and at least one first raised piece 304. The first raised piece 304 is formed by processing the first opening 303, and first raised piece 304 is connected to the main body area 347. A first raised angle a3 between the main body area 347 and the first raised piece 304 can be between 5 degrees and 175 degrees. Accordingly, the heat dissipation area of the interior of the closed shape is increased.

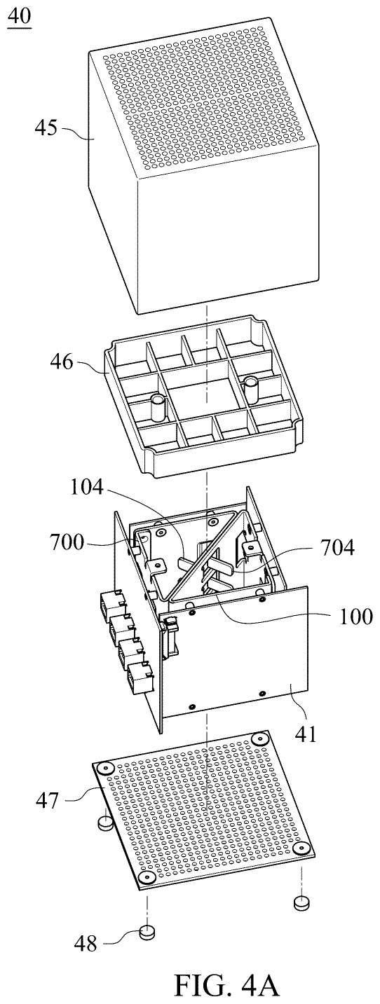

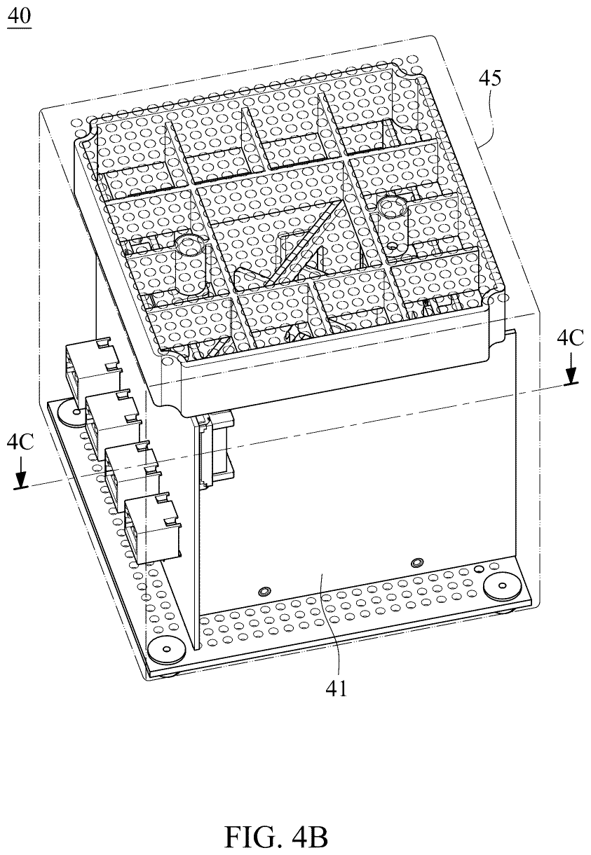

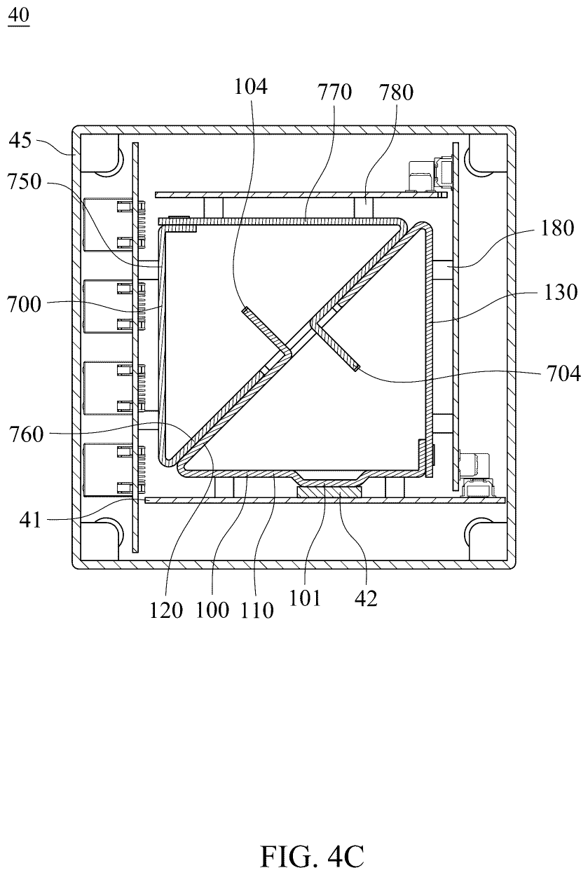

FIG. 4A illustrates an exploded view of an electronic device 40 according to a fourth embodiment of the present disclosure, FIG. 4B illustrates a three-dimensional view of the electronic device 40 in FIG. 4A, and FIG. 4C illustrates a cross-sectional view of partial elements of the electronic device 40 along line 4C-4C in FIG. 4B. Referring to FIGS. 4A to 4C, the electronic device 40 may include at least one of the aforementioned first heat sink unit 100, second heat sink unit 700, and heat sink units 200, 300, and the present disclosure is not limited thereto. In the fourth embodiment, the electronic device 40 includes the heat sink assembly 10 (including the first heat sink unit 100 and the second heat sink unit 700) of the first embodiment and at least one circuit board assembly; the number of the at least one circuit board assembly is specifically four. Each circuit board assembly includes a circuit board 41 and at least one electronic component 42; one or multiple electronic components 42 are disposed on the corresponding circuit board 41 and connected to the protrusion 101 or protrusion 701. Accordingly, the electronic device 40 includes the heat sink assembly 10 according to the present disclosure, which is advantageous in reducing cost and weight, while maintaining heat dissipation efficiency.

In detail, one of the four circuit boards 41 may be parallel to the first plate portion 110. Accordingly, the protrusion 101 can be designed on the heat sink assembly 10 and its first plate portion 110, to provide heat dissipation for the heat source on the circuit board 41. Specifically, the four circuit boards 41 are respectively parallel to the first plate portion 110, the third plate portion 130, the seventh plate portion 770, and the fifth plate portion 750. Furthermore, the electronic device 40 may specifically be a router and may further include a main casing 45, an antenna bracket 46, a lower casing 47, and foot pads 48. The heat sink assembly 10 and the four circuit board assemblies are connected to the antenna bracket 46 and fixed inside the main casing 45 and the lower casing 47.

In other embodiments of the present disclosure (not shown in the drawings), the electronic device may include the heat sink unit 200 of the second embodiment and at least one circuit board assembly. The first plate portion 210 includes the main body area 217 and the step structure 207, with the step surface 208 protruding from the outer surface 215 of the first plate portion 210 and connected to the circuit board or electronic component in the circuit board assembly. Accordingly, various heat dissipation structures can be designed using the bending flexibility of the original plate 200a, to meet various heat source distribution requirements.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A heat sink unit, comprising:
a first plate portion, the first plate portion being integrally formed and comprising an outer surface, an inner surface, and at least one protrusion; and
a second plate portion, the second plate portion being connected to the first plate portion;
wherein a first angle between the first plate portion and the second plate portion is between 5 degrees and 175 degrees, the outer surface of the first plate portion is farther from the second plate portion than the inner surface therefrom, and the at least one protrusion is located on the outer surface.

2. The heat sink unit according to claim 1, wherein the at least one protrusion is not connected to two opposite edges of the first plate portion.

3. The heat sink unit according to claim 1, wherein the first plate portion and the second plate portion are integrally formed from a metal material, and a thickness of a main body area of each of the first plate portion and the second plate portion is between 0.8 mm and 3 mm.

4. The heat sink unit according to claim 3, wherein the first plate portion and the second plate portion are formed by bending an original plate, and the at least one protrusion is formed by sheet metal forming of the first plate portion.

5. The heat sink unit according to claim 1, further comprising:
at least one third plate portion, wherein the first plate portion, the second plate portion, and the at least one third plate portion are sequentially connected and form a closed shape.

6. The heat sink unit according to claim 5, wherein the closed shape is a triangle or a quadrilateral.

7. The heat sink unit according to claim 6, further comprising:
at least one fourth plate portion, located on an inner side of the closed shape and connected to at least one plate portion of the first plate portion and the at least one third plate portion.

8. The heat sink unit according to claim 7, wherein the first plate portion, the second plate portion, the at least one third plate portion, and the at least one fourth plate portion are formed by bending an original plate along a surrounding direction.

9. The heat sink unit according to claim 7, wherein the at least one fourth plate portion comprises at least one main body area, at least one first opening, and at least one first raised piece, the at least one first raised piece is formed by processing the at least one first opening, the at least one first raised piece is connected to the at least one main body area, and a first raised angle between the at least one main body area and the at least one first raised piece is between 5 degrees and 175 degrees.

10. The heat sink unit according to claim 1, wherein at least one plate portion of the first plate portion and the second plate portion comprises at least one main body area, at least one first opening, and at least one first raised piece, the at least one first raised piece is formed by processing the at least one first opening, the at least one first raised piece is connected to the at least one main body area, and a first raised angle between the at least one main body area and the at least one first raised piece is between 5 degrees and 175 degrees.

11. The heat sink unit according to claim 1, wherein a plate portion of the first plate portion and the second plate portion comprises a main body area and a step structure, one end of the step structure is connected to the main body area, the other end of the step structure is an open end, and the step structure has a step shape and comprises a plurality of step surfaces.

12. The heat sink unit according to claim 11, wherein one of the step surfaces protrudes from an outer surface of the plate portion and is parallel to the main body area.

13. The heat sink unit according to claim 1, further comprising:
at least one fin element, the at least one fin element being connected to at least one plate portion of the first plate portion and the second plate portion.

14. A heat sink assembly, comprising:
a first heat sink unit, comprising:
a first plate portion, the first plate portion comprising at least one protrusion; and
a second plate portion, the second plate portion being connected to the first plate portion, wherein the first plate portion and the second plate portion are integrally formed, and a first angle between the first plate portion and the second plate portion is between 5 degrees and 175 degrees; and
a second heat sink unit, comprising:
a fifth plate portion; and
a sixth plate portion, the sixth plate portion being connected to the fifth plate portion, wherein a second angle between the fifth plate portion and the sixth plate portion is between 5 degrees and 175 degrees;
wherein the first heat sink unit is connected to the second heat sink unit.

15. The heat sink assembly according to claim 14, wherein the first plate portion and the second plate portion are formed by bending an original plate of a metal material, and the fifth plate portion and the sixth plate portion are formed by bending another original plate of a metal material.

16. The heat sink assembly according to claim 14, further comprising:
at least one third plate portion, wherein the first plate portion, the second plate portion, and the at least one third plate portion are sequentially connected and form a closed shape; and
at least one seventh plate portion, wherein the fifth plate portion, the sixth plate portion, and the at least one seventh plate portion are sequentially connected and form another closed shape;
wherein a portion of an outer surface of the second plate portion is connected to the sixth plate portion, and a ratio of an area of the portion to an area of the outer surface of the second plate portion is between 0.5 and 1.

17. The heat sink assembly according to claim 14, wherein a plate portion of the first plate portion and the second plate portion comprises a main body area, a plurality of first openings, and a plurality of first raised pieces, each of the first raised pieces is formed by processing a corresponding one of the first openings, each of the first raised pieces is connected to the main body area, and a first raised angle between the main body area and each of the first raised pieces is between 5 degrees and 175 degrees;
wherein a plate portion of the fifth plate portion and the sixth plate portion comprises another main body area, a plurality of second openings, and a plurality of second raised pieces, each of the second raised pieces is formed by processing a corresponding one of the second openings, each of the second raised pieces is connected to the another main body area, and a second raised angle between the another main body area and each of the second raised pieces is between 5 degrees and 175 degrees;
wherein the main body area is connected to the another main body area, the first raised pieces respectively pass through the second openings, and the second raised pieces respectively pass through the first openings.

18. An electronic device, comprising:
a heat sink unit, comprising:
a first plate portion, comprising at least one protrusion; and
a second plate portion, the second plate portion being connected to the first plate portion, wherein the first plate portion and the second plate portion are integrally formed, and a first angle between the first plate portion and the second plate portion is between 5 degrees and 175 degrees; and
at least one circuit board assembly, comprising at least one circuit board and at least one electronic component, the least one electronic component being disposed on the at least one circuit board and connected to the at least one protrusion.

19. The electronic device according to claim 18, wherein the at least one circuit board is parallel to at least one of the first plate portion and the second plate portion.

20. The electronic device according to claim 18, wherein a plate portion of the first plate portion and the second plate portion comprises a main body area and a step structure, the step structure has a step shape and comprises a plurality of step surfaces, and one of the step surfaces protrudes from an outer surface of the plate portion and is connected to the at least one circuit board assembly.
